(19) United States
(12) Patent Application Publication
(10) Pub. No.: US 2026/0215162 A1
(43) Pub. Date: Jul. 23, 2026

(54) MAGNETORESISTIVE EFFECT ELEMENT AND MAGNETIC MEMORY DEVICE

(71) Applicant: Kioxia Corporation, Tokyo (JP)

(72) Inventor: Kenji NOMA, Yokkaichi (JP)

(21) Appl. No.: 19/323,078

(22) Filed: Sep. 9, 2025

(30) Foreign Application Priority Data
Jan. 20, 2025 (JP) 2025-007488

(51) Int. Cl. H10N 50/10; G11C 11/16; H01F 10/32; H10N 50/85

(52) U.S. Cl. CPC H10N 50/10; G11C 11/161; G11C 11/1673; G11C 11/1675; H01F 10/3272; H10N 50/85

(57) ABSTRACT

A magnetoresistive effect element includes a first antiferromagnetic layer, a second antiferromagnetic layer, a free magnetization layer provided between the first antiferromagnetic layer and the second antiferromagnetic layer, a tunnel barrier layer provided between the free magnetization layer and the second antiferromagnetic layer, a first fixed magnetization layer provided between the tunnel barrier layer and the second antiferromagnetic layer, an antiparallel coupling layer provided between the first fixed magnetization layer and the second antiferromagnetic layer, and a second fixed magnetization layer provided between the antiparallel coupling layer and the second antiferromagnetic layer.

### CROSS-REFERENCE TO RELATED APPLICATION

This application is based upon and claims the benefit of priority from Japanese Patent Application No. 2025-007488, filed Jan. 20 , 2025, the entire contents of which are incorporated herein by reference.

### FIELD

Embodiments described herein relate generally to a magnetoresistive effect element and a magnetic memory device.

### BACKGROUND

A static random access memory (SRAM) and a dynamic random access memory (DRAM) are generally widely used as solid-state memories adopting random access methods. Another practical solid-state memory that allows random access is a magnetic random access memory (MRAM). However, compared to SRAM and DRAM, MRAM is only used in small quantities. The reason is that SRAM has a high read/write speed and a small capacity and DRAM has a low read/write speed but a large capacity, while MRAM has a read/write speed slightly lower than that of SRAM and a capacity smaller than that of DRAM. Therefore, MRAM has a performance that is intermediate between SRAM and DRAM, so that SRAM and DRAM are sufficient for most memory applications. Thus, to make MRAM as widespread as SRAM and DRAM, it is preferable to implement either a speed higher as SRAM or a capacity larger as DRAM.

### DESCRIPTION OF THE DRAWINGS

FIG. 1 is a block diagram showing a configuration of a magnetic memory device according to an embodiment;

FIG. 2 is a schematic cross-sectional view showing a configuration of a memory cell of the magnetic memory device according to the embodiment;

FIGS. 3A and 3B are schematic cross-sectional views showing a configuration of a magnetoresistive effect element of the magnetic memory device according to the embodiment;

FIGS. 4A and 4B are schematic cross-sectional views showing a write voltage and a magnetization direction of the magnetoresistive effect element of the magnetic memory device according to the embodiment;

FIGS. 5A to 5E show a magnetization direction of a free magnetization layer when φ=77.5 degrees, θ=150 degrees, a magnetization direction of a first fixed magnetization layer is upward, and a voltage of −1.35 V or −1.55 V with a pulse width of 1 nS is applied;

FIG. 6 shows applied voltage V_{TE} dependency of a write result when a magnetization angle φ is changed between 70 degrees or more and 89.5 degrees or less; and

FIG. 7 shows applied voltage V_{TE} dependency of a write result when φ=77.5 degrees and θ is set to 0 degrees or more and 345 degrees or less.

### DETAILED DESCRIPTION

Embodiments provide a magnetoresistive effect element capable of implementing large-capacity storage.

In general, according to one embodiment, a magnetoresistive effect element includes a first antiferromagnetic layer, a second antiferromagnetic layer, a free magnetization layer provided between the first antiferromagnetic layer and the second antiferromagnetic layer, a tunnel barrier layer provided between the free magnetization layer and the second antiferromagnetic layer, a first fixed magnetization layer provided between the tunnel barrier layer and the second antiferromagnetic layer, an antiparallel coupling layer provided between the first fixed magnetization layer and the second antiferromagnetic layer, and a second fixed magnetization layer provided between the antiparallel coupling layer and the second antiferromagnetic layer. An angle of a direction of an exchange coupling magnetic field of the first antiferromagnetic layer is equal to or greater than 76 degrees and equal to or less than 86 degrees with respect to a film surface of the free magnetization layer. An angle of a direction of an exchange coupling magnetic field of the second antiferromagnetic layer is equal to or greater than 76 degrees and equal to or less than 86 degrees with respect to the film surface of the free magnetization layer. An angle of a direction of magnetic anisotropy of the first fixed magnetization layer is equal to or greater than 76 degrees and equal to or less than 86 degrees with respect to the film surface of the free magnetization layer. An angle of a direction of magnetic anisotropy of the second fixed magnetization layer is equal to or greater than 76 degrees and equal to or less than 86 degrees with respect to the film surface of the free magnetization layer.

Hereinafter, an embodiment will be described with reference to the drawings. It should be noted that, in the drawings, the same or similar parts are denoted by the same or similar reference numerals.

In the specification, an upward direction in the drawing will be described as “upper” and a lower direction in the drawing will be described as “lower” to indicate relative positions of parts, and the like. In the specification, concepts of “upper” and “lower” do not necessarily refer to the direction of gravity.

### EMBODIMENT

A magnetoresistive effect element according to an embodiment includes a first antiferromagnetic layer, a second antiferromagnetic layer, a free magnetization layer provided between the first antiferromagnetic layer and the second antiferromagnetic layer, a tunnel barrier layer provided between the free magnetization layer and the second antiferromagnetic layer, a first fixed magnetization layer provided between the tunnel barrier layer and the second antiferromagnetic layer, an antiparallel coupling layer provided between the first fixed magnetization layer and the second antiferromagnetic layer, and a second fixed magnetization layer provided between the antiparallel coupling layer and the second antiferromagnetic layer. An angle of a direction of an exchange coupling magnetic field of the first antiferromagnetic layer is 76 degrees or more and 86 degrees or less with respect to a film surface of the free magnetization layer, an angle of a direction of an exchange coupling magnetic field of the second antiferromagnetic layer is 76 degrees or more and 86 degrees or less with respect to the film surface of the free magnetization layer, an angle of a direction of magnetic anisotropy of the first fixed magnetization layer is 76 degrees or more and 86 degrees or less with respect to the film surface of the free magnetization layer, and an angle of a direction of magnetic anisotropy of the second fixed magnetization layer is 76 degrees or more and 86 degrees or less with respect to the film surface of the free magnetization layer.

A magnetic memory device according to an embodiment includes a magnetoresistive effect element, a voltage application device, and a transistor electrically connected to the magnetoresistive effect element and the voltage application device.

The magnetic memory device according to the embodiment is, for example, a magnetic random access memory (MRAM) using a perpendicular magnetization type magnetic tunnel junction (MTJ) magnetization method in which a magnetoresistive effect element including an MTJ element is used as a memory element.

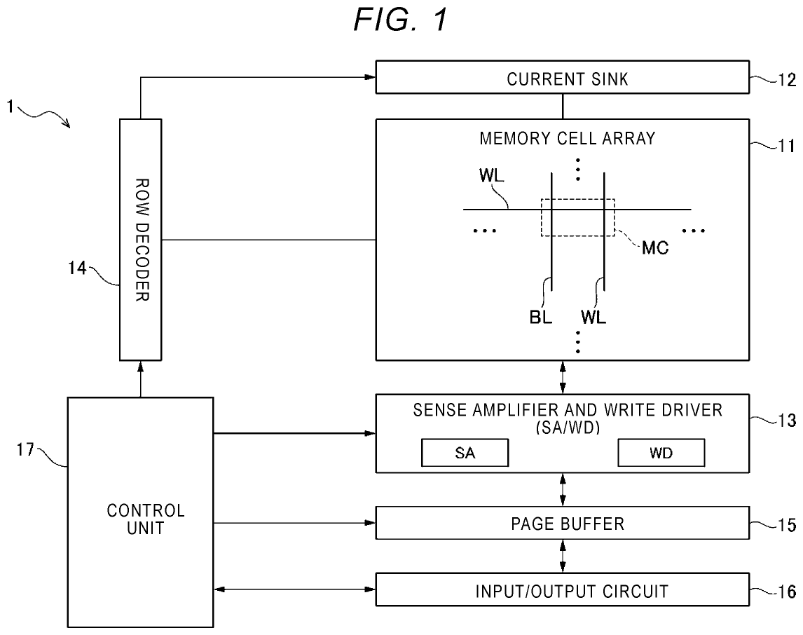

FIG. 1 is a block diagram showing a configuration of the magnetic memory device according to the embodiment. As shown in FIG. 1, a magnetic memory device 1 includes a memory cell array 11, a current sink 12, a sense amplifier and write driver (SA/WD) 13 (an example of a voltage application device), a row decoder 14, a page buffer 15, an input/output circuit 16, and a control unit 17.

The memory cell array 11 includes a plurality of memory cells MC associated with rows and columns. For example, the memory cells MC in the same row are connected to the same word line WL, and both ends of the memory cells MC in the same column are connected to the same bit line BL and the same source line SL.

The current sink 12 is connected to the bit line BL and the source line SL. The current sink 12 sets the bit line BL or the source line SL to a ground voltage during operations such as writing and reading of data.

The SA/WD 13 is connected to the bit line BL and the source line SL. The SA/WD 13 supplies a current to the memory cell MC as an operation target via the bit line BL and the source line SL, and writes data to the memory cell MC. The SA/WD 13 also supplies a voltage to the memory cell MC as an operation target via the bit line BL and a word line WL, and reads data from the memory cell MC. More specifically, a write driver of the SA/WD 13 writes data to the memory cell MC, and a sense amplifier of the SA/WD 13 reads data from the memory cell MC.

The row decoder 14 is connected to the memory cell array 11 via the word line WL. The row decoder 14 decodes a row address that designates a row direction of the memory cell array 11. Then, a word line WL is selected depending on a decoding result, and a voltage required for operations such as writing and reading of data is applied to the selected word line WL.

The page buffer 15 temporarily stores data to be written into the memory cell array 11 and data read out from the memory cell array 11 in data units referred to as pages.

The input/output circuit 16 transmits various signals received from outside of the magnetic memory device 1 to the control unit 17 and the page buffer 15, and transmits various types of information from the control unit 17 and the page buffer 15 to outside of the magnetic memory device 1.

The control unit 17 is connected to the current sink 12, the SA/WD 13, the row decoder 14, the page buffer 15, and the input/output circuit 16. The control unit 17 controls the current sink 12, the SA/WD 13, the row decoder 14, and the page buffer 15 in response to various signals received by the input/output circuit 16 from outside of the magnetic memory device 1.

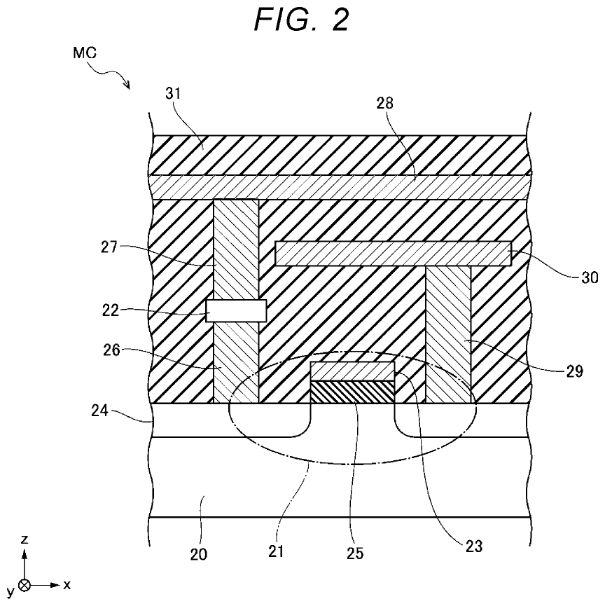

Next, a configuration of the memory cell of the magnetic memory device according to the embodiment will be described with reference to FIG. 2. In the following description, a plane parallel to a semiconductor substrate 20 is defined as an xy plane, and an axis perpendicular to the xy plane is defined as a z axis. An x axis and a y axis are defined as axes orthogonal to each other in the xy plane. FIG. 2 shows an example of a cross-sectional view when the memory cell MC of the magnetic memory device 1 according to the embodiment is taken along an xz plane.

As shown in FIG. 2, the memory cell MC is provided on the semiconductor substrate 20 and includes a select transistor 21 (an example of a transistor) and a magnetoresistive effect element 22. The select transistor 21 is provided as a switch that controls supply and stop of a current when writing and reading data to and from the magnetoresistive effect element 22. The magnetoresistive effect element 22 includes a plurality of stacked films, and can switch a resistance value between a low resistance state and a high resistance state by applying a current in a direction perpendicular to the film surface. The magnetoresistive effect element 22 functions as a memory element capable of writing data by changing a resistance state, storing the written data in a non-volatile manner, and allowing the data to be read.

The select transistor 21 includes a gate connected to a wiring layer 23 functioning as a word line WL, and a pair of source or drain regions 24 provided on the surface of the semiconductor substrate 20 at both ends of the gate in the x direction. A region of the select transistor 21 provided in the semiconductor substrate 20 is referred to as an active region. The active regions are insulated from each other by element isolation regions (shallow trench isolation (STI)) (not shown) so that the active regions are not electrically connected to active regions of other memory cells MC, for example.

The wiring layer 23 is provided in the y direction via an insulating layer 25 on the semiconductor substrate 20, and is connected in common to gates of select transistors 21 (not shown) of other memory cells MC arranged in the y direction. The wiring layers 23 are arranged in the x direction, for example.

One end of the select transistor 21 is electrically connected to a lower surface of the magnetoresistive effect element 22 via a contact plug 26 electrically connected to the source region or drain region 24. A contact plug 27 is provided on an upper surface of the magnetoresistive effect element 22. The magnetoresistive effect element 22 is connected to a wiring layer 28 functioning as the bit line BL via the contact plug 27. The wiring layer 28 extends in the x direction, and is connected in common to the other ends of the magnetoresistive effect elements 22 of other memory cells MC (not shown) arranged in the x direction, for example.

The wiring layer 28 and a wiring layer 30 are arranged, for example, in the y direction. The wiring layer 28 is located, for example, above the wiring layer 30. It should be noted that the wiring layers 28 and 30 are disposed to avoid physical and electrical interference with each other. The select transistor 21, the magnetoresistive effect element 22, the wiring layer 23, the wiring layer 28, the wiring layer 30, the contact plug 26, the contact plug 27, and a contact plug 29 are covered by an interlayer insulating film 31.

It should be noted that other magnetoresistive effect elements 22 (not shown) arranged in the x direction or the y direction with respect to the magnetoresistive effect element 22 are provided, for example, on the same layer. That is, in the memory cell array 11, the plurality of magnetoresistive effect elements 22 are arranged, for example, in a direction in which the semiconductor substrate 20 extends.

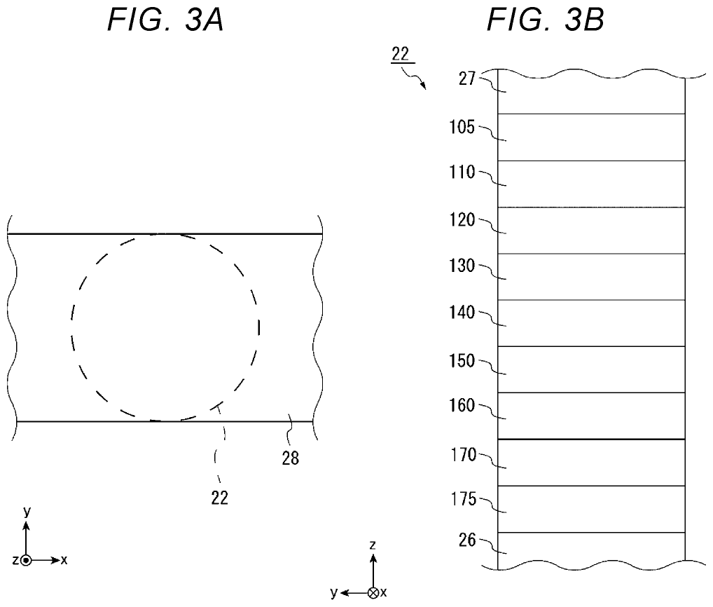

Next, a configuration of the magnetoresistive effect element 22 of the magnetic memory device according to the embodiment will be described with reference to FIGS. 3A and 3B. FIGS. 3A and 3B are schematic diagrams of the magnetoresistive effect element 22 according to the embodiment. FIG. 3A is an example of a schematic top view of the magnetoresistive effect element 22 according to the embodiment when viewed in the z direction. It should be noted that FIG. 3A also shows a schematic diagram of the wiring layer 28. FIG. 3B is an example of a cross-sectional view of the magnetoresistive effect element 22 of the magnetic memory device according to the embodiment taken along a plane perpendicular to the xz plane. It should be noted that FIG. 3B also shows the contact plug 27 and the contact plug 26.

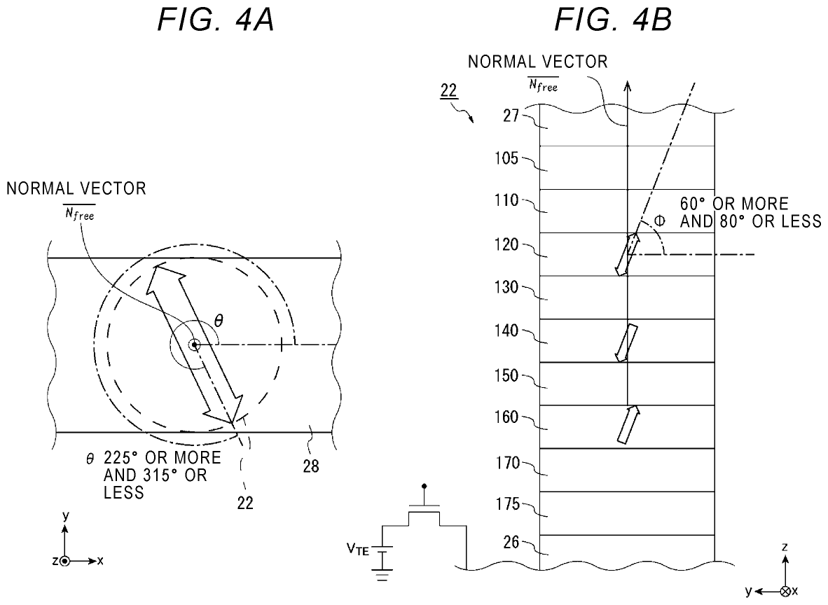

FIGS. 4A and 4B are schematic diagrams showing a write voltage and a magnetization direction of the magnetoresistive effect element of the magnetic memory device according to the embodiment. FIGS. 4A and 4B also show an angle θ and an angle φ of magnetization of a free magnetization layer 120. The angle θ is an angle between the magnetization of the free magnetization layer 120 and the x direction. When the magnetization of the free magnetization layer 120 is parallel to the x direction, the angle θ is zero degrees. The angle φ is an angle between the magnetization of the free magnetization layer 120 and the xy plane. When the magnetization of the free magnetization layer 120 is parallel to the xy plane, the angle φ is zero degrees.

The magnetoresistive effect element 22 includes a first antiferromagnetic layer 110, the free magnetization layer 120, a tunnel barrier layer 130, a first fixed magnetization layer 140, an antiparallel coupling layer 150, a second fixed magnetization layer 160, and a second antiferromagnetic layer 170.

The magnetoresistive effect element 22 is an element in which a plurality of layers (films) are stacked in the z-axis direction, for example, in the order of an underlayer 175, the second antiferromagnetic layer 170, the second fixed magnetization layer 160, the antiparallel coupling layer 150, the first fixed magnetization layer 140, the tunnel barrier layer 130, the free magnetization layer 120, the first antiferromagnetic layer 110, and a cap layer 105 from the contact plug 26 side. A shape of the magnetoresistive effect element 22 in a plane parallel to the xy plane is, for example, circular.

The magnetoresistive effect element 22 is, for example, a perpendicular magnetization type MTJ element in which magnetization directions of the free magnetization layer 120, the first fixed magnetization layer 140, and the second fixed magnetization layer 160 are each perpendicular to a stacking surface (film surface).

The second antiferromagnetic layer 170 contains, for example, platinum-manganese (PtMn), palladium-manganese (PdMn), iridium-manganese (IrMn), or Fe-manganese (FeMn). The second antiferromagnetic layer 170 is preferably a platinum-manganese (PtMn) film, a palladium-manganese (PdMn) film, an iridium-manganese (IrMn) film, or a Fe-manganese (FeMn) film. An angle of a direction of an exchange coupling magnetic field of the second antiferromagnetic layer 170 is 76 degrees or more and 86 degrees or less with respect to the film surface of the free magnetization layer 120.

It should be noted that the film surface of the free magnetization layer 120 is, for example, parallel to the xy plane and perpendicular to the z axis.

For example, by using a (100) oriented platinum-manganese (PtMn) film, palladium-manganese (PdMn) film, iridium-manganese (IrMn) film, or Fe-manganese (FeMn) film, the angle of the direction of the exchange coupling magnetic field of the second antiferromagnetic layer 170 can be set to 76 degrees or more and 86 degrees or less with respect to the film surface of the free magnetization layer 120.

It should be noted that a normal direction of the free magnetization layer 120 is, for example, the z-axis direction or the-z-axis direction. The normal direction of the free magnetization layer 120 is, for example, a direction from the second antiferromagnetic layer 170 to the first antiferromagnetic layer 110. The normal direction of the free magnetization layer 120 is, for example, a direction in which the underlayer 175, the second antiferromagnetic layer 170, the second fixed magnetization layer 160, the antiparallel coupling layer 150, the first fixed magnetization layer 140, the tunnel barrier layer 130, the free magnetization layer 120, the first antiferromagnetic layer 110, and the cap layer 105 are stacked.

The second fixed magnetization layer 160 is a layer having electrical conductivity and containing a ferromagnetic material. The second fixed magnetization layer 160 contains an element including at least one of iron (Fe), cobalt (Co), and nickel (Ni), for example. The second fixed magnetization layer 160 may further contain at least one of boron (B), phosphorus (P), carbon (C), aluminum (Al), silicon (Si), tantalum (Ta), molybdenum (Mo), chromium (Cr), hafnium (Hf), tungsten (W), and titanium (Ti). More specifically, for example, the second fixed magnetization layer 160 may contain at least one of cobalt iron boron (CoFeB) or iron boride (FeB), cobalt Fe (CoFe), cobalt platinum (CoPt), cobalt nickel (CoNi), and cobalt palladium (CoPd). An angle of a direction of magnetic anisotropy of the second fixed magnetization layer is 76 degrees or more and 86 degrees or less with respect to the film surface of the free magnetization layer 120.

The antiparallel coupling layer 150 is a nonmagnetic electrically conductive film. The antiparallel coupling layer 150 contains at least one element selected from, for example, ruthenium (Ru), osmium (Os), iridium (Ir), vanadium (V), and chromium (Cr).

The first fixed magnetization layer 140 is a layer having electrical conductivity and containing a ferromagnetic material. The first fixed magnetization layer 140 contains an element including at least one of, for example, iron (Fe), cobalt (Co), and nickel (Ni). The first fixed magnetization layer 140 may further contain at least one of, for example, boron (B), phosphorus (P), carbon (C), aluminum (Al), silicon (Si), tantalum (Ta), molybdenum (Mo), chromium (Cr), hafnium (Hf), tungsten (W), and titanium (Ti). More specifically, for example, the first fixed magnetization layer 140 may contain at least one of cobalt iron boron (CoFeB) or iron boride (FeB), cobalt Fe (CoFe), cobalt platinum (CoPt), cobalt nickel (CoNi), and cobalt palladium (CoPd). An angle of a direction of magnetic anisotropy of the first fixed magnetization layer 140 is 76 degrees or more and 86 degrees or less with respect to the film surface of the free magnetization layer 120.

The first fixed magnetization layer 140 and the second fixed magnetization layer 160 are coupled by the antiparallel coupling layer 150 so that the layers 140 and 160 have antiparallel or substantially antiparallel magnetization directions. In other words, the first fixed magnetization layer 140 and the second fixed magnetization layer 160 are antiferromagnetically coupled by the antiparallel coupling layer 150.

The tunnel barrier layer 130 is a layer including an insulator, and enables electrical conduction between the first fixed magnetization layer 140 and the free magnetization layer 120 by a tunnel effect. The tunnel barrier layer 130 contains, for example, magnesium oxide (MgO) or aluminum oxide (AlO).

The free magnetization layer 120 is a layer having electrical conductivity and containing a ferromagnetic material. The free magnetization layer 120 contains at least one of iron (Fe), cobalt (Co), and nickel (Ni). The free magnetization layer 120 may further contain at least one of boron (B), phosphorus (P), carbon (C), aluminum (Al), silicon (Si), tantalum (Ta), molybdenum (Mo), chromium (Cr), hafnium (Hf), tungsten (W), and titanium (Ti). More specifically, for example, the free magnetization layer 120 may contain cobalt iron boron (CoFeB) or iron boride (FeB). The free magnetization layer 120 has a magnetization direction toward either the contact plug 26 side or the contact plug 27 side. The magnetization direction of the free magnetization layer 120 is set to be easily reversed compared to the magnetization direction of the first fixed magnetization layer 140.

The first fixed magnetization layer 140, the tunnel barrier layer 130, and the free magnetization layer 120 have a magnetic tunnel coupling.

The first antiferromagnetic layer 110 contains, for example, platinum-manganese (PtMn), palladium-manganese (PdMn), iridium-manganese (IrMn), or Fe-manganese (FeMn). The second antiferromagnetic layer 170 is preferably a platinum-manganese (PtMn) film, a palladium-manganese (PdMn) film, an iridium-manganese (IrMn) film, or a Fe-manganese (FeMn) film. An angle of a direction of an exchange coupling magnetic field of the first antiferromagnetic layer 110 is 76 degrees or more and 86 degrees or less with respect to the film surface of the free magnetization layer 120.

For example, by using a (100) oriented platinum-manganese (PtMn) film, palladium-manganese (PdMn) film, iridium-manganese (IrMn) film, or Fe-manganese (FeMn) film, the angle of the direction of the exchange coupling magnetic field of the first antiferromagnetic layer 110 can be set to 76 degrees or more and 86 degrees or less with respect to the film surface of the free magnetization layer 120.

An exchange coupling energy Jₑₓ between the first antiferromagnetic layer 110 and the free magnetization layer 120 is set to, for example, approximately 5×10⁻⁴ J/m².

The magnetoresistive effect element 22 may further include the underlayer 175 containing, for example, tantalum (Ta) or ruthenium nitride (RuN) between the contact plug 26 and the second antiferromagnetic layer 170.

The magnetoresistive effect element 22 may further include the cap layer 105 containing, for example, tantalum (Ta) or ruthenium nitride (RuN) between the contact plug 27 and the first antiferromagnetic layer 110.

Writing and reading of the magnetoresistive effect element 22 according to the embodiment are performed by applying a voltage to the magnetoresistive effect element 22 using the sense amplifier and write driver (SA/WD) 13. When a voltage is applied to the magnetoresistive effect element 22, a voltage-controlled magnetic anisotropy (VCMA) occurs. VCMA is a phenomenon that occurs when a voltage is applied to a magnetic layer via an insulating layer in which an anisotropic magnetic field of the magnetic layer decreases in proportion to an electric field strength in the insulating layer.

For example, when a voltage is applied to the second fixed magnetization layer 160 with the free magnetization layer 120 as zero voltage, the anisotropic magnetic field of the free magnetization layer 120 decreases in proportion to an electric field strength generated in the tunnel barrier layer 130.

Here, when the anisotropic magnetic field of the free magnetization layer 120 decreases and becomes lower than a magnetic flux density from the first fixed magnetization layer 140, the magnetization direction of the free magnetization layer 120 becomes parallel to the magnetization direction of the first fixed magnetization layer 140. When the anisotropic magnetic field of the free magnetization layer 120 decreases due to a further increase in voltage and becomes lower than a magnetic flux density from the second fixed magnetization layer 160, the magnetization direction of the free magnetization layer 120 is tilted to the direction of a sum of a leakage magnetic field from the first fixed magnetization layer 140 and a leakage magnetic field from the second fixed magnetization layer 160. In other words, assuming that a case where the magnetization of the free magnetization layer 120 is oriented in the magnetization direction of the first fixed magnetization layer 140 is “0” and a case where the magnetization of the free magnetization layer 120 is oriented in the magnetization direction of the second fixed magnetization layer 160 is “1”, states of “0” and “1” of the magnetoresistive effect element 22 can be controlled by controlling a strength of a VCMA voltage applied from the sense amplifier and write driver (SA/WD) 13.

A product Mₛ₁t₁ of an effective film thickness t₁ and a saturation magnetization Mₛ₁ of the first fixed magnetization layer 140 and a product Mₛ₂t₂ of an effective film thickness t₂ and a saturation magnetization Mₛ₂ of the second fixed magnetization layer 160 have a relationship of Mₛ₁t₁<Mₛ₂t₂, and it is preferable that the sum of the leakage magnetic fields from the second fixed magnetization layer 160 at the position of the free magnetization layer 120 be greater than the sum of the leakage magnetic fields from the first fixed magnetization layer 140.

It is preferable that an exchange coupling magnetic field between the first antiferromagnetic layer 110 and the free magnetization layer 120 be smaller than a coercive force of the free magnetization layer 120 in a direction parallel to a direction of the exchange coupling magnetic field between the first antiferromagnetic layer 110 and the free magnetization layer 120.

It is preferable that a total magnetic moment μ_{AF} of the first antiferromagnetic layer 110 and a total magnetic moment μ_{free} of the free magnetization layer 120 have a relationship of 1.2 μ_{free}<μ_{AF}<1.4 μ_{free}.

It is preferable that an effective magnetic anisotropy constant K and a saturation magnetization Ms of each of the free magnetization layer 120, the first fixed magnetization layer 140, and the second fixed magnetization layer have a relationship of K>2πMs².

It is preferable that an exchange coupling magnetic field between the second fixed magnetization layer 160 and the second antiferromagnetic layer 170 be greater than a coercive force of the second fixed magnetization layer 160 parallel to a direction of the exchange coupling magnetic field between the second fixed magnetization layer 160 and the second antiferromagnetic layer 170.

Next, a method of manufacturing the magnetoresistive effect element 22 and the magnetic memory device 1 according to the embodiment will be described.

The current sink 12, the sense amplifier and write driver (SA/WD) 13, the row decoder 14, the page buffer 15, the input/output circuit 16, and the control unit 17 (FIG. 1) (none of which are shown in FIG. 2) are formed on the semiconductor substrate 20 using a semiconductor process. Next, the source region or drain region 24, the insulating layer 25, and the wiring layer 23 are formed on the semiconductor substrate 20. Thereby, the select transistor 21 is formed. Next, the interlayer insulating film 31 is formed on the select transistor 21, for example, by a chemical vapor deposition (CVD) method. Next, after forming a contact hole by, for example, an RIE method, the contact plug 26 is appropriately formed by, for example, a CVD method.

Next, the magnetoresistive effect element 22 is formed to be electrically connected to the contact plug 26 and to include the underlayer 175, the second antiferromagnetic layer 170, the second fixed magnetization layer 160, the antiparallel coupling layer 150, the first fixed magnetization layer 140, the tunnel barrier layer 130, the free magnetization layer 120, the first antiferromagnetic layer 110, and the cap layer 105. Next, a heat treatment is performed on the magnetoresistive effect element 22 while applying a magnetic field in a direction tilted by 4 degrees or more and 14 degrees or less from the z axis (a direction tilted by 76 degrees or more and 86 degrees or less from the xy plane) so that the angle of the direction of the exchange coupling magnetic field of the first antiferromagnetic layer 110, the angle of the direction of the exchange coupling magnetic field of the second antiferromagnetic layer 170, the angle of the direction of magnetic anisotropy of the first fixed magnetization layer 140, and the angle of the direction of magnetic anisotropy of the second fixed magnetization layer 160 are set to 76 degrees or more and 86 degrees or less with respect to the film surface of the free magnetization layer 120. Next, a photoresist pattern (not shown) is formed, and the magnetoresistive effect element 22 is patterned. Here, an etching gas used for patterning may be a chlorine gas, a mixed gas of a CO gas and an NH₃ gas, methyl alcohol, or the like.

Next, the contact plug 29, the contact plug 27, the wiring layer 30, the wiring layer 28, and the interlayer insulating film 31 are appropriately formed to obtain the magnetic memory device 1 according to the embodiment.

Next, effects of the magnetoresistive effect element and the magnetic memory device according to the embodiment will be described.

In recent years, SRAM has reached a miniaturization limit due to an increase in leakage current. Therefore, although an operation speed is slightly low, an advantage of using MRAM having a small leakage current is becoming greater. Recently, there has been an increase in use of MRAM in a secondary cache of a processor. Development is ongoing to apply MRAM to a primary cache and a CPU register due to further increases in speed. Meanwhile, to replace DRAM with MRAM, there is a problem that a storage capacity of MRAM is smaller than a storage capacity of DRAM.

When writing to a spin transfer torque (STT) type MRAM, currents of different magnitudes are applied in two directions. For example, an MTJ element used in STT type MRAM includes a multilayer film including a free magnetization layer, a tunnel barrier layer, a fixed magnetization layer, an antiferromagnetic coupling layer, and a shift adjustment layer. To change the MTJ element into a low resistance state (“0” state), a current of, for example, approximately several tens of μA is applied in a direction from the free magnetization layer to the fixed magnetization layer. To change the MTJ element into a high resistance state (“1” state), a current of, for example, approximately several tens to several hundreds of μA is applied in the direction of from the fixed magnetization layer to the free magnetization layer. It should be noted that magnetization directions of the free magnetization layer, the fixed magnetization layer, and the antiferromagnetic coupling layer are, for example, either perpendicular or parallel to the film surface. As such, to perform writing to one MTJ in the MRAM, two transistors are required to apply two types of currents with different magnitudes and directions. In other words, a unit memory cell of MRAM is configured with one MTJ element and two transistors (has a 1M2T configuration).

Meanwhile, a unit memory cell of DRAM is configured with one capacitor and one transistor (1C1T). Therefore, when manufactured with the same chip area/dimension, a capacity of MRAM is less than half of a capacity of DRAM. Accordingly, to replace DRAM with MRAM, it is preferable to change a configuration of the unit memory cell from a 1M2T configuration to a 1M1T configuration.

In the magnetoresistive effect element 22 according to the embodiment, the angle of the direction of the exchange coupling magnetic field of the first antiferromagnetic layer 110 is 76 degrees or more and 86 degrees or less with respect to the film surface of the free magnetization layer 120. The angle of the direction of the exchange coupling magnetic field of the second antiferromagnetic layer 170 is 76 degrees or more and 86 degrees or less with respect to the film surface of the free magnetization layer 120. The direction of the magnetic anisotropy of the first fixed magnetization layer 140 is 76 degrees or more and 86 degrees or less with respect to the film surface of the free magnetization layer 120. The direction of the magnetic anisotropy of the second fixed magnetization layer 160 is 76 degrees or more and 86 degrees or less with respect to the film surface of the free magnetization layer 120. In such a magnetoresistive effect element 22, states of “0” and “1” can be controlled by changing a strength of a voltage applied from the sense amplifier and write driver (SA/WD) 13 using a VCMA phenomenon. Therefore, using the magnetoresistive effect element 22 according to the embodiment, the configuration of the unit memory cell of the magnetic memory device 1 can be set to a 1M1T configuration.

The magnetoresistive effect element 22 according to the embodiment has a high resistance, and only a current that is, for example, six to seven orders of magnitude smaller than that of DRAM or the like flows. Therefore, the magnetic memory device 1 using the magnetoresistive effect element 22 according to the embodiment consumes less power than DRAM. A so-called refresh performed in DRAM is not required. Since only a small current flows as described above, reliability is high and a write latency is extremely short compared to a normal STT type MRAM. The magnetic memory device 1 according to the embodiment can have a smaller footprint compared to SRAM configured using six transistors. Accordingly, it is possible to provide a magnetoresistive effect element capable of implementing large-capacity storage.

The magnetoresistive effect element 22 according to the embodiment includes two antiferromagnetic layers. In other words, the magnetoresistive effect element 22 according to the embodiment includes the first antiferromagnetic layer 110 and the second antiferromagnetic layer 170. By providing the first antiferromagnetic layer 110, a latch effect can be exhibited when the magnetization of the free magnetization layer 120 is reversed. In other words, when the magnetization of the free magnetization layer 120 is reversed, it is possible to prevent overshooting and returning to the original direction. To maintain the magnetization direction of the free magnetization layer 120 and stored information, it is preferable to provide the first antiferromagnetic layer 110.

The product Mₛ₁t₁ of the effective film thickness t₁ and the saturation magnetization Mₛ₁ of the first fixed magnetization layer 140 and the product Mₛ₂t₂ of the effective film thickness t₂ and the saturation magnetization Mₛ₂ of the second fixed magnetization layer 160 have a relationship of Mₛ₁t₁<Mₛ₂t₂, and it is preferable that the sum of the leakage magnetic fields from the second fixed magnetization layer 160 at the position of the free magnetization layer 120 be greater than the sum of the leakage magnetic fields from the first fixed magnetization layer 140. By satisfying the relationship of Mₛ₁t₁<Mₛ₂t₂, a stronger leakage magnetic field from the first fixed magnetization layer 140 is applied to an end of the free magnetization layer 120. Thereby, it becomes easier for the magnetization direction of the free magnetization layer 120 to be reversed by a VCMA phenomenon.

In magnetoresistive effect elements used in magnetic heads of hard disks (magnetic disks), Mₛt of a fixed magnetization layer closer to a free magnetization layer is usually smaller than Mₛt of a fixed magnetization layer farther from the free magnetization layer, unlike the magnetoresistive effect element according to the embodiment.

The first antiferromagnetic layer 110 and the second antiferromagnetic layer 170 are preferably a platinum-manganese film, a palladium-manganese film, an iridium-manganese film, or an iron-manganese film. The reason is that it is possible to form an antiferromagnetic layer with high characteristics.

The exchange coupling magnetic field between the first antiferromagnetic layer 110 and the free magnetization layer 120 is preferably smaller than the coercive force of the free magnetization layer 120 in the direction parallel to the direction of the exchange coupling magnetic field between the first antiferromagnetic layer 110 and the free magnetization layer 120. The reason is that, when the exchange coupling magnetic field between the first antiferromagnetic layer 110 and the free magnetization layer 120 is equal to or greater than the coercive force of the free magnetization layer 120 in the direction parallel to the direction of the exchange coupling magnetic field between the first antiferromagnetic layer 110 and the free magnetization layer 120, the magnetization direction of the free magnetization layer 120 is easily influenced by the exchange coupling magnetic field of the first antiferromagnetic layer 110, so that it becomes difficult to store information using the magnetization of the free magnetization layer 120.

When the total magnetic moment μ_{AF} of the first antiferromagnetic layer 110 and the total magnetic moment μ_{free} of the free magnetization layer 120 have a relationship of 1.2 μ_{free}<μ_{AF}<1.4 μ_{free}, information can be stored suitably in the magnetoresistive effect element 22 using a VCMA phenomenon.

To configure the magnetic memory device 1 as a magnetic memory device using a perpendicular magnetization method, it is preferable that the effective magnetic anisotropy constant K and the saturation magnetization Ms have a relationship of K>2πMs² in each of the free magnetization layer 120, the first fixed magnetization layer 140, and the second fixed magnetization layer 160.

The exchange coupling magnetic field between the second fixed magnetization layer 160 and the second antiferromagnetic layer 170 is preferably larger than the coercive force of the second fixed magnetization layer 160 parallel to the direction of the exchange coupling magnetic field between the second fixed magnetization layer 160 and the second antiferromagnetic layer 170. The reason is that, when the exchange coupling magnetic field between the second fixed magnetization layer 160 and the second antiferromagnetic layer 170 is equal to or smaller than the coercive force of the second fixed magnetization layer 160 parallel to the direction of the exchange coupling magnetic field between the second fixed magnetization layer 160 and the second antiferromagnetic layer 170, it becomes difficult to fix the magnetization direction of the second fixed magnetization layer 160.

### EXAMPLE

The magnetoresistive effect element 22 according to the embodiment was simulated by micromagnetic calculation. The magnetoresistive effect element 22 had a film configuration in which a tantalum film with a thickness of 1 nm and a ruthenium nitride film with a thickness of 2 nm were used as the underlayer 175, an iridium-manganese film with a film thickness of 7 nm was used as the second antiferromagnetic layer 170, a cobalt-iron film with a film thickness of 0.9 nm was used as the second fixed magnetization layer 160, a ruthenium film with a film thickness of 0.4 nm was used as the antiparallel coupling layer 150, a cobalt-iron-boron (B) film with a film thickness of 1.1 nm was used as the first fixed magnetization layer 140, a magnesium oxide film with a film thickness of 1.4 nm was used as the tunnel barrier layer 130, a cobalt-iron-boron film with a film thickness of 1.1 nm was used as the free magnetization layer 120, an iridium-manganese film with a film thickness of 1.6 nm was used as the first antiferromagnetic layer 110, and a tantalum film with a film thickness of 10 nm was used as the cap layer 105. It should be noted that the shape of the magnetoresistive effect element 22 in a plane parallel to the XY plane was a circle with a diameter of 20 nm.

Here, the saturation magnetization Mₛ₂ of the cobalt-iron film used as the second fixed magnetization layer 160 was 2.0 T. The saturation magnetization Mₛ₁ of the cobalt-iron-boron film used as the first fixed magnetization layer 140 was 1.2 T. Mₛ₁t₁ of the first fixed magnetization layer 140 was 1.32 T·nm, and Mₛ₂t₂ of the second fixed magnetization layer 160 was 1.8 T·nm. Therefore, a relationship of Mₛ₁t₁<Mₛ₂t₂ was satisfied. It was confirmed by micromagnetic calculation that the sum of the leakage magnetic fields from the second fixed magnetization layer 160 was greater than the sum of the leakage magnetic fields from the first fixed magnetization layer 140 at the position of the free magnetization layer 120. The total magnetic moment μ_{AF} of the first antiferromagnetic layer 110 and the total magnetic moment μ_{free} of the free magnetization layer 120 had a relationship of approximately μ_{AF}=1.3 μ_{free}.

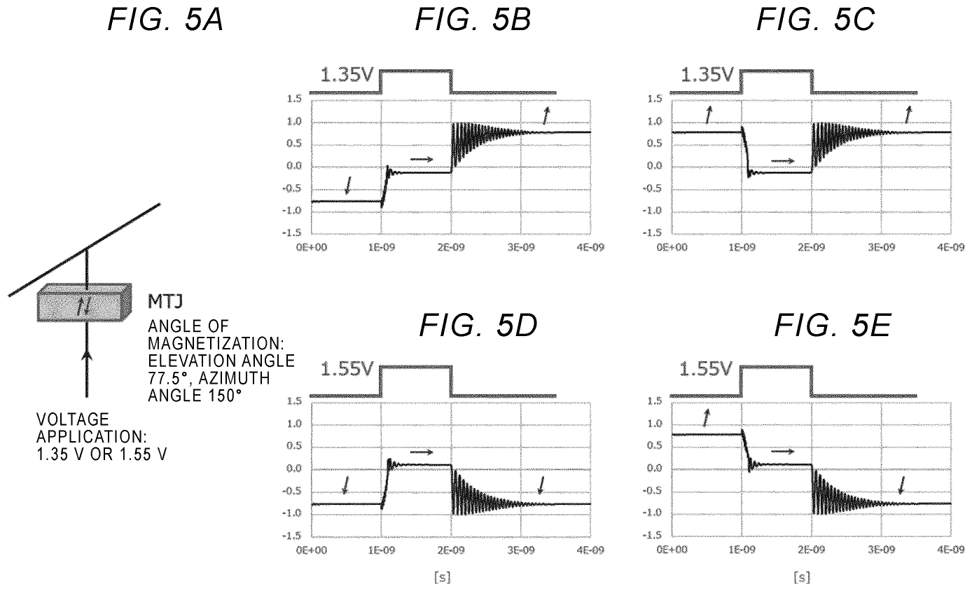

First, a magnetization response when a voltage was applied is shown. FIGS. 5A to 5E show the magnetization direction of the free magnetization layer 120 when φ (elevation angle)=77.5 degrees, θ (azimuth angle)=150 degrees, the magnetization of the first fixed magnetization layer 140 was upward, and a voltage of −1.35 V or −1.55 V with a pulse width of 1 nS was applied. Here, when a vertical axis of a graph is +0.78, it means that the magnetization of the free magnetization layer 120 is upward, in other words, “0” that is parallel to the magnetization of the first fixed magnetization layer 140, and when the vertical axis of the graph is −0.77, it means that the magnetization of the free magnetization layer 120 is downward, in other words, “1” that is antiparallel to the magnetization of the first fixed magnetization layer 140. As shown in FIGS. 5A to 5E, when a voltage of −1.35 V is applied to a location where the initial state is “1” (downward), the magnetization is reversed to the “0” (upward) state, and when a voltage of −1.55 V is applied, the magnetization is once substantially oriented into the plane and then returns to the original “1” state when the voltage application is stopped. Meanwhile, when a voltage of −1.55 V is applied to a location where the initial state is “0” (upward), the magnetization is reversed to a “1” (downward) state, and when a voltage of-1.35 V is applied, the magnetization is once substantially oriented into the plane and returns to the original “0” state when the voltage application is stopped. That is, regardless of the original state, when a voltage of −1.35 V is applied, the state of “0” can be set, and when a voltage of −1.55 V is applied, the state of “1” can be set. It means that overwriting required for a random access memory is possible. In an STT type MRAM, a current is applied in upward and downward directions to implement overwriting, and thus a total of two transistors are provided for each magnetoresistive effect element. Meanwhile, in the magnetic memory device according to the embodiment, overwriting can be performed simply by applying voltages of different values from the same side, and thus only one transistor is provided for each magnetoresistive effect element. Therefore, it is possible to provide a magnetoresistive effect element capable of implementing large-capacity storage.

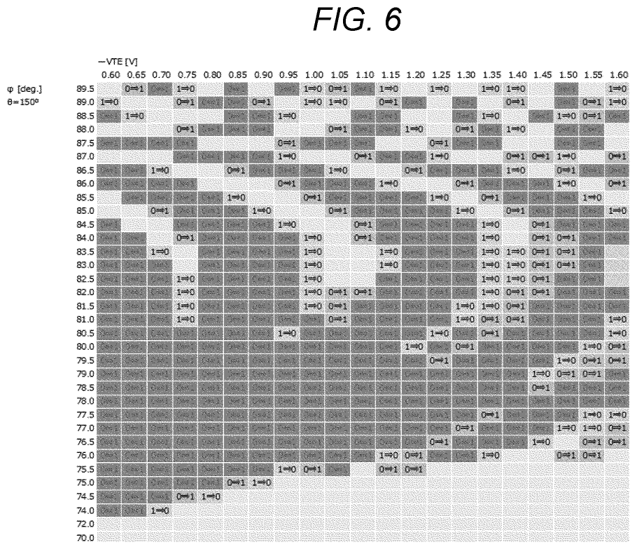

Next, FIG. 6 shows applied voltage V_{TE} dependency of a write result when the magnetization angle φ of the free magnetization layer 120 is changed to 70 degrees or more and 89.5 degrees or less. Here, 0→1 means that, when a value before writing is “0”, the value can be changed to “1”, but when the value before writing is “1”, the value remains as “1”, that is, writing of “0” does not occur. 1→0 means that, when a value before writing is “1”, the value can be changed to “0”, but when the value before writing is “0”, writing of “1” does not occur. 0↔ 1 means that both 0→1 and 1→0 occur, so-called toggle writing. Finally, a blank space means that no reversal occurs. It should be noted that no magnetization reversal of the free magnetization layer 120 occurs when φ=90 degrees corresponding to a perpendicular magnetization film or φ<72.0 degrees, even when an applied voltage V_{TE} was changed. Meanwhile, a condition was found that magnetization reversal occurs at V_{TE}<1.6 V when 75.5 degrees≤φ≤89.5 degrees. It should be noted that, in FIG. 6, θ=150 degrees is set. It means that magnetization control in any direction by VCMA can be implemented by tilting a magnetization angle from the Z direction.

To find an optimum condition for φ using FIG. 6, it is desirable that both 0→1 and 1→0 appear by viewing at FIG. 6 in the lateral direction, and voltage values of both are as far apart as possible. When φ=77.5 degrees as shown in FIGS. 5A to 5E, 0→1 is −1.35 V, and 1→0 is −1.55 V to −1.60 V, thereby satisfying the requirement. Looking at other φ values capable of satisfying the requirement, an angle of 76 degrees≤φ≤86 degrees with respect to the film surface (xy plane) of the free magnetization layer 120 is suitable.

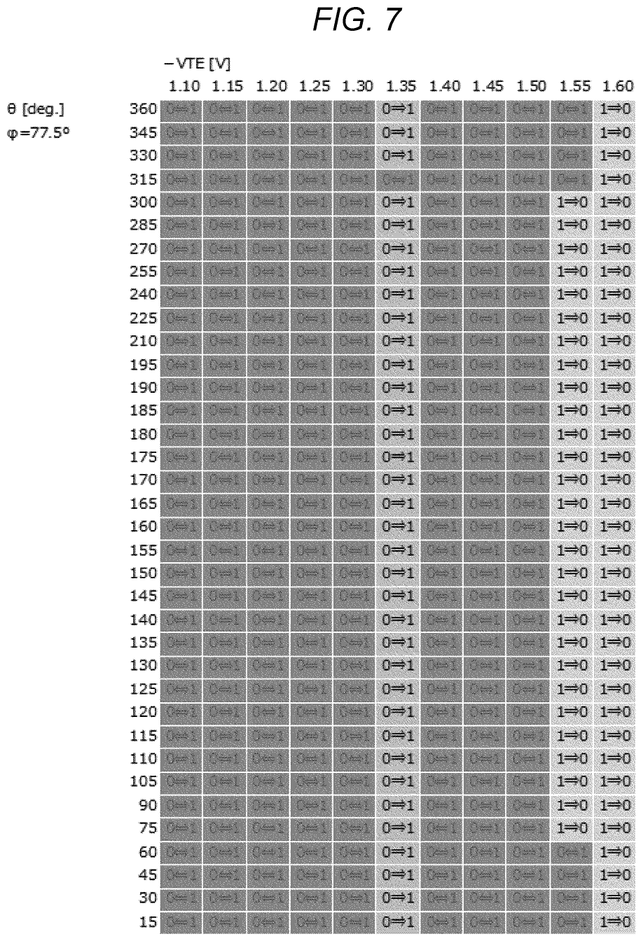

Next, FIG. 7 shows applied voltage V_{TE} dependency of a write result when φ=77.5 degrees and θ is set to 0 degrees or more and 345 degrees or less. It is confirmed that writing of “1” can be performed when V_{TE}=−1.35 V or V_{TE}<−1.6 V, and writing of “0” can be performed when V_{TE}=−1.6 V, and that dependence of the writable V_{TE} value on θ is almost zero. The reason is that an electric field to be generated has only a component perpendicular to the plane, resulting in the magnitude of a torque acting on the magnetization being dependent on φ but independent of θ.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A magnetoresistive effect element comprising:
a first antiferromagnetic layer;
a second antiferromagnetic layer;
a free magnetization layer provided between the first antiferromagnetic layer and the second antiferromagnetic layer;
a tunnel barrier layer provided between the free magnetization layer and the second antiferromagnetic layer;
a first fixed magnetization layer provided between the tunnel barrier layer and the second antiferromagnetic layer;
an antiparallel coupling layer provided between the first fixed magnetization layer and the second antiferromagnetic layer; and
a second fixed magnetization layer provided between the antiparallel coupling layer and the second antiferromagnetic layer, wherein
an angle of a direction of an exchange coupling magnetic field of the first antiferromagnetic layer is equal to or greater than 76 degrees and equal to or less than 86 degrees with respect to a film surface of the free magnetization layer,
an angle of a direction of an exchange coupling magnetic field of the second antiferromagnetic layer is equal to or greater than 76 degrees and equal to or less than 86 degrees with respect to the film surface of the free magnetization layer,
an angle of a direction of magnetic anisotropy of the first fixed magnetization layer is equal to or greater than 76 degrees and equal to or less than 86 degrees with respect to the film surface of the free magnetization layer, and
an angle of a direction of magnetic anisotropy of the second fixed magnetization layer is equal to or greater than 76 degrees and equal to or less than 86 degrees with respect to the film surface of the free magnetization layer.

2. The magnetoresistive effect element according to claim 1, wherein
a product Mₛ₁t₁ of an effective film thickness t₁ and a saturation magnetization Mₛ₁ of the first fixed magnetization layer and a product Mₛ₂t₂ of an effective film thickness t₂ and a saturation magnetization Mₛ₂ of the second fixed magnetization layer have a relationship of Mₛ₁t₁<Mₛ₂t₂, and
a sum of leakage magnetic fields from the second fixed magnetization layer at a position of the free magnetization layer is greater than a sum of leakage magnetic fields from the first fixed magnetization layer.

3. The magnetoresistive effect element according to claim 1, wherein the first antiferromagnetic layer and the second antiferromagnetic layer form a platinum-manganese film, a palladium-manganese film, an iridium-manganese film, or an iron-manganese film.

4. The magnetoresistive effect element according to claim 1, wherein an exchange coupling magnetic field between the first antiferromagnetic layer and the free magnetization layer is less than a coercive force of the free magnetization layer in a direction parallel to a direction of the exchange coupling magnetic field between the first antiferromagnetic layer and the free magnetization layer.

5. The magnetoresistive effect element according to claim 1, wherein a total magnetic moment μ_{AF} of the first antiferromagnetic layer and a total magnetic moment μ_{free} of the free magnetization layer have a relationship of 1.2μ_{free}<μ_{AF}<1.4μ_{free}.

6. The magnetoresistive effect element according to claim 1, wherein an effective magnetic anisotropy constant K and a saturation magnetization Ms have a relationship of K>2πMs² in each of the free magnetization layer, the first fixed magnetization layer, and the second fixed magnetization layer.

7. The magnetoresistive effect element according to claim 1, wherein a magnetization direction of the first fixed magnetization layer and a magnetization direction of the second fixed magnetization layer are substantially antiparallel.

8. The magnetoresistive effect element according to claim 1, wherein an exchange coupling magnetic field between the second fixed magnetization layer and the second antiferromagnetic layer is greater than a coercive force of the second fixed magnetization layer parallel to a direction of the exchange coupling magnetic field between the second fixed magnetization layer and the second antiferromagnetic layer.

9. A magnetic memory device comprising:
the magnetoresistive effect element according to claim 1;
a voltage application device; and
a transistor electrically connected to the magnetoresistive effect element and the voltage application device.

10. A magnetic memory device comprising:
a magnetoresistive effect element;
a voltage application device; and
a transistor electrically connected to the magnetoresistive effect element and the voltage application device;
wherein the magnetoresistive effect element comprises:
a first antiferromagnetic layer;
a second antiferromagnetic layer;
a free magnetization layer provided between the first antiferromagnetic layer and the second antiferromagnetic layer;
a tunnel barrier layer provided between the free magnetization layer and the second antiferromagnetic layer;
a first fixed magnetization layer provided between the tunnel barrier layer and the second antiferromagnetic layer;
an antiparallel coupling layer provided between the first fixed magnetization layer and the second antiferromagnetic layer; and
a second fixed magnetization layer provided between the antiparallel coupling layer and the second antiferromagnetic layer, wherein
an angle of a direction of an exchange coupling magnetic field of the first antiferromagnetic layer is equal to or greater than 76 degrees and equal to or less than 86 degrees with respect to a film surface of the free magnetization layer,
an angle of a direction of an exchange coupling magnetic field of the second antiferromagnetic layer is equal to or greater than 76 degrees and equal to or less than 86 degrees with respect to the film surface of the free magnetization layer,
an angle of a direction of magnetic anisotropy of the first fixed magnetization layer is equal to or greater than 76 degrees and equal to or less than 86 degrees with respect to the film surface of the free magnetization layer, and
an angle of a direction of magnetic anisotropy of the second fixed magnetization layer is equal to or greater than 76 degrees and equal to or less than 86 degrees with respect to the film surface of the free magnetization layer.
